(19) United States
(12) Patent Application Publication
(10) Pub. No.: US 2026/0333726 A1
(43) Pub. Date: Oct. 22, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Takahiro KATO, Nonoichi Ishikawa (JP); Tatsuo NAIJO, Hakusan Ishikawa (JP); Masato WADA, Nomi Ishikawa (JP)

(21) Appl. No.: 19/547,595

(22) Filed: Feb. 23, 2026

(30) Foreign Application Priority Data
Apr. 17, 2025 (JP) 2025-068131

(51) Int. Cl. H10D 12/00; H10D 62/13

(52) U.S. Cl. CPC H10D 12/481; H10D 62/142

(57) ABSTRACT

A semiconductor device includes a first electrode, a collector layer, a first buffer layer, a second buffer layer, a drift layer, a base layer, an emitter layer, a second electrode, a third electrode and a gate insulating film. R1<R2<(R3−R4−Wmax) is satisfied. R1 is a distance from the upper surface to an apex of the first peak. R2 is a distance from the upper surface to an apex of the second peak. R3 is a distance from the upper surface to the lower surface. R4 is a distance from the lower portion to the lower surface. Wmax is a width of a maximum depletion layer of the drift layer at turn-off.

### CROSS-REFERENCE TO RELATED APPLICATIONS

This application is based upon and claims the benefit of priority from Japanese Patent Application No. 2025-068131, filed on Apr. 17, 2025; the entire contents of which are incorporated herein by reference.

### FIELD

Embodiments described herein relate generally to a semiconductor device.

### BACKGROUND

For example, in a semiconductor device, it is desirable to suppress an increase of the peak voltage and suppress oscillations after turn-off.

### BRIEF DESCRIPTION OF THE DRAWINGS

FIG. 1 is a schematic cross-sectional view illustrating a semiconductor device according to an embodiment;

FIG. 2 is a schematic view showing impurity concentrations of each buffer layer between a first electrode and a second electrode and distances between the components of the semiconductor device according to the embodiment;

FIG. 3 is a schematic view showing a carrier concentration with respect to the depth from the first electrode of the semiconductor device according to the embodiment;

FIG. 4 is a schematic view describing the width of a maximum depletion layer of the semiconductor device according to the embodiment;

FIG. 5 describes a total dose of a dose of a drift layer and a dose of a second buffer layer of the semiconductor device according to the embodiment;

FIG. 6 describes conditions of the total dose of the semiconductor device according to the embodiment based on simulation results;

FIG. 7 illustrates characteristics when the distance from an upper surface to the apex of a second peak is less than a prescribed distance;

FIG. 8 shows the relationship of a peak voltage between the first electrode and the third electrode with respect to the distance from the upper surface to the apex of the second peak;

FIG. 9 shows results showing the presence or absence of oscillation waveforms of areas A3 and A4 of FIG. 7, in which a total dose Qdp and a distance R2 are changed;

FIG. 10 shows the relationship of the peak voltage between the first electrode and the third electrode with respect to the distance from the upper surface to the apex of the second peak;

FIG. 11 shows the relationship of the peak voltage between the first electrode and the third electrode with respect to the distance from the upper surface to the apex of the second peak;

FIG. 12 shows the relationship of the peak voltage between the first electrode and the third electrode with respect to the distance from the upper surface to the apex of the second peak;

FIG. 13 shows the relationship of the peak voltage between the first electrode and the third electrode with respect to the distance from the upper surface to the apex of the second peak; and

FIG. 14 is simulation results showing presence or absence of oscillations of voltage waveforms of samples with respect to a concentration peak value of a second impurity concentration.

### DETAILED DESCRIPTION

In general, according to one embodiment, a semiconductor device includes a first electrode, a collector layer, a first buffer layer, a second buffer layer, a drift layer, a base layer, an emitter layer, a second electrode, a third electrode and a gate insulating film. The first electrode includes an upper surface. The collector layer is located on the first electrode. The collector layer is of a second conductivity type. The first buffer layer is located on the collector layer. The first buffer layer is of a first conductivity type and includes a first impurity. The second buffer layer is located on the first buffer layer. The second buffer layer is of the first conductivity type and includes a second impurity. The drift layer is located on the second buffer layer. The drift layer is of the first conductivity type and includes a third impurity. The base layer is located on the drift layer. The base layer is of the second conductivity type. The emitter layer is located on the base layer. The emitter layer is of the first conductivity type. The second electrode is located on the emitter layer. The second electrode includes a lower surface. The third electrode is located between a portion of the second electrode and a portion of the drift layer. The gate insulating film is located at least between the third electrode and the base layer. The gate insulating film includes a lower portion. The first buffer layer includes a first peak of a concentration of the first impurity in a first direction. The first direction is from the first electrode toward the second electrode. The second buffer layer includes a second peak of a concentration of the second impurity in the first direction. R1<R2<(R3−R4−Wmax) is satisfied. R1 is a distance from the upper surface to an apex of the first peak. R2 is a distance from the upper surface to an apex of the second peak. R3 is a distance from the upper surface to the lower surface. R4 is a distance from the lower portion to the lower surface. Wmax is a width of a maximum depletion layer of the drift layer at turn-off. Wmax is expressed by formula (1), q is an absolute value of a charge of an electron, ε is a permittivity of the drift layer, Nd is a concentration of the third impurity of the drift layer, Vs is a saturation velocity of holes, Vce is a voltage between the first electrode and the third electrode, Ic is a rated current, γₕ is a ratio of a hole current at turn-off, AA is an area of the second electrode in a plane including a second direction and a third direction. The second direction crosses the first direction. The third direction crosses the first and second directions.

$${W}_{max} = \sqrt{\frac{2 ε {V}_{ce}}{( {N}_{d} + \frac{{I}_{c} {γ}_{h}}{{qV}_{s} \times AA} )}} \qquad ( 1 )$$

Qdp>4.27×10⁻³×Nd+2.41×10¹¹ cm⁻² is satisfied, Qdp (cm⁻²) is a total dose of a dose of the drift layer and a dose of the second buffer layer, Nd has units of cm⁻³. Nproton<1.8×10¹⁵/cm³ is satisfied, Nproton is a concentration of the second peak.

Various embodiments are described below with reference to the accompanying drawings.

The drawings are schematic or conceptual; and the relationships between the thickness and width of portions, the proportions of sizes among portions, etc., are not necessarily the same as the actual values. The dimensions and proportional coefficients may be illustrated differently among drawings, even for identical portions.

In the specification and drawings, components similar to those described previously or illustrated in an antecedent drawing are marked with the same reference numerals; and a detailed description is omitted as appropriate.

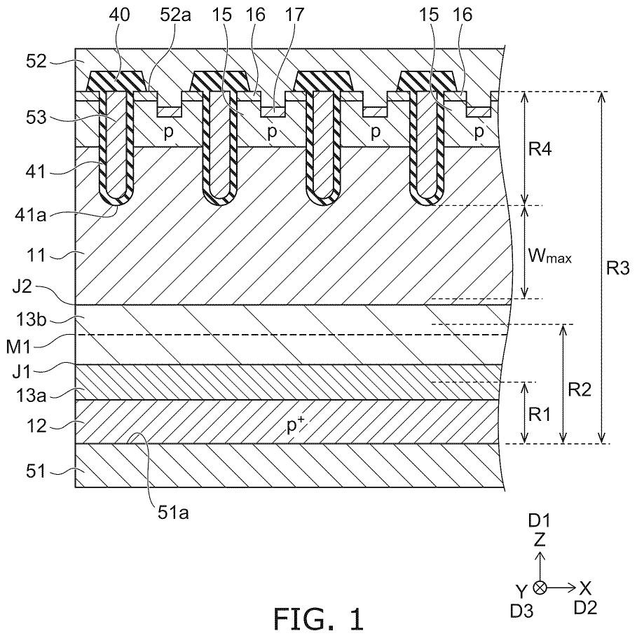

FIG. 1 is a schematic cross-sectional view illustrating a semiconductor device according to an embodiment.

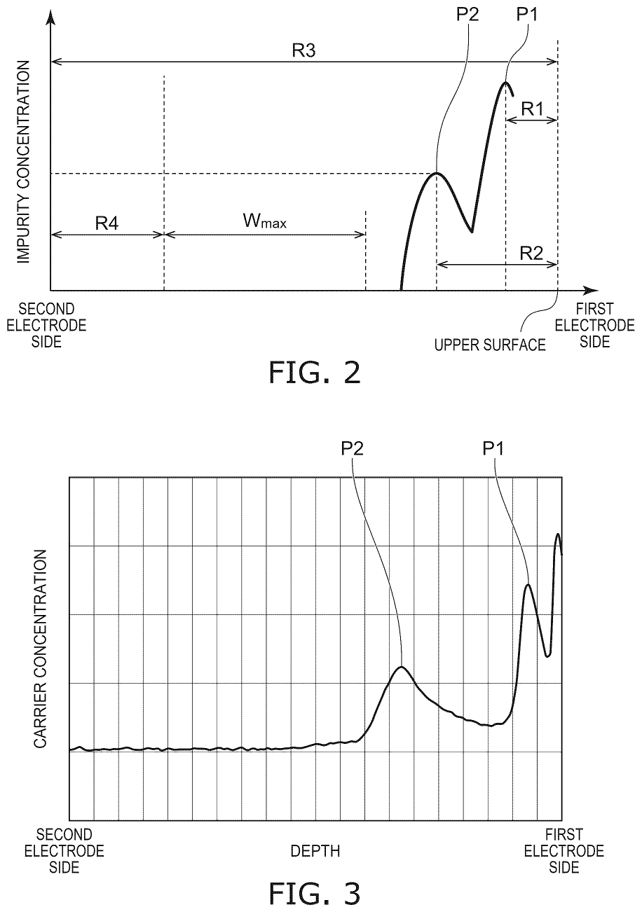

FIG. 2 is a schematic view showing impurity concentrations of each buffer layer between a first electrode and a second electrode and distances between the components of the semiconductor device according to the embodiment. FIG. 2 shows the impurity concentration of each buffer layer, distances from an upper surface 51a of a first electrode 51 to peaks of impurity concentrations, the width of the maximum depletion layer of a drift layer 11 at turn-off, a trench depth, etc.

FIG. 3 is a schematic view showing a carrier concentration with respect to the depth from the first electrode of the semiconductor device according to the embodiment.

In the description, the direction from the first electrode 51 toward a second electrode 52 is referred to as “up/above”; and the opposite direction is referred to as “down/below”. These directions are based on the relative positional relationship between the first electrode 51 and the second electrode 52, and are independent of the direction of gravity.

As shown in FIG. 1, the semiconductor device 100 includes the first electrode 51, a collector layer 12, a first buffer layer 13a, a second buffer layer 13b, the drift layer 11, a base layer 15, an emitter layer 16, the second electrode 52, a third electrode 53, and a gate insulating film 41. The semiconductor device 100 may further include a contact layer 17 and an insulating layer 40.

The first electrode 51 includes the upper surface 51a. The upper surface 51a is the surface of the first electrode 51 at the collector layer 12 side. The collector layer 12 is located on the first electrode 51. The collector layer 12 is of a second conductivity type.

The first buffer layer 13a is located on the collector layer 12. The first buffer layer 13a includes a first impurity. The first buffer layer 13a is of a first conductivity type. The second buffer layer 13b is located on the first buffer layer 13a. The second buffer layer 13b includes a second impurity. The second buffer layer 13b is of the first conductivity type. The first conductivity type may be, for example, an n-type. The second conductivity type may be, for example, a p-type.

The base layer 15 is located on the drift layer 11. The base layer 15 is of the second conductivity type. The emitter layer 16 is located on a portion of the base layer 15. The emitter layer 16 is of the first conductivity type. The contact layer 17 is located on a portion of the base layer 15.

The impurity concentration of the contact layer 17 may be greater than the impurity concentration of the base layer 15.

The second electrode 52 is positioned on the base layer 15, the emitter layer 16, and the contact layer 17 and is electrically connected to these regions. The third electrode 53 is insulated from the second electrode 52 by the insulating layer 40.

The second electrode 52 includes a lower surface 52a. The lower surface 52a is the surface of the second electrode 52 at the drift layer 11 side. The lower surface 52a of the second electrode 52 contacts the emitter layer 16. The third electrode 53 is located between a portion of the second electrode 52 and a portion of the drift layer 11. The gate insulating film 41 is located at least between the third electrode 53 and the base layer 15. The gate insulating film 41 insulates the drift layer 11, the base layer 15, and the emitter layer 16 from the third electrode 53. The gate insulating film 41 includes a lower portion 41a. The lower portion 41a is the portion of the gate insulating film 41 positioned at the second buffer layer 13b side. The lower portion 41a also is the portion of the trench positioned at the second buffer layer 13b side.

A voltage that is not less than a threshold is applied to the third electrode 53 in a state in which a voltage that is positive relative to the second electrode 52 is applied to the first electrode 51. As a result, a channel (an inversion layer) is formed in the p-type base layer 15. The current that flows between the first electrode 51 and the second electrode 52 can be controlled according to the potential of the third electrode 53. The first electrode 51 is, for example, a collector electrode. The second electrode 52 is, for example, an emitter electrode. The third electrode 53 is, for example, a gate electrode. The semiconductor device 100 is, for example, an IGBT (Insulated Gate Bipolar Transistor). FIG. 1 shows only an IGBT region. The semiconductor device 100 may include the IGBT region and a diode region. Multiple IGBT regions and multiple diode regions may be arranged in the X-direction and Y-direction. The IGBT region and the diode region may be alternately arranged in the X-direction.

Here, if primarily the drift layer 11 is thinned, there is a risk that the peak voltage may increase and oscillations may occur after turn-off. Therefore, in the semiconductor device 100 according to the embodiment, this problem is solved by forming the first buffer layer 13a and the second buffer layer 13b with proton irradiation, by setting appropriate positions of apexes of a first peak P1 and a second peak P2, which are described below, and by setting appropriate impurity concentrations. Details are described below.

As shown in FIGS. 1, 2, and 3, the first buffer layer 13a includes the first peak P1 having a first impurity concentration in a first direction D1; and the first direction D1 is from the first electrode 51 toward the second electrode 52. The first direction D1 from the first electrode 51 toward the second electrode 52 is taken as a Z-axis direction. One direction perpendicular to the Z-axis direction is taken as an X-axis direction. A direction perpendicular to the Z-axis direction and the X-axis direction is taken as a Y-axis direction. The X-axis direction is, for example, a second direction D2. The second buffer layer 13b includes the second peak P2 having a second impurity concentration in the first direction D1. The impurity concentration of the first peak P1 is greater than the impurity concentration of the second peak P2. FIG. 3 shows a peak of the impurity concentration of the collector layer 12 positioned between the first buffer layer 13a and the first electrode 51. The impurity concentration of the peak of the impurity concentration profile of the collector layer 12 is greater than the impurity concentration of the first peak P1.

FIGS. 1 and 2 show a distance R1 from the upper surface 51a to the apex of the first peak P1, a distance R2 from the upper surface 51a to the apex of the second peak P2, a distance R3 from the upper surface 51a to the lower surface 52a, a distance R4 from the lower portion 41a to the lower surface 52a, and a width Wmax of the maximum depletion layer of the drift layer 11 at turn-off. The width Wmax can be estimated as an amount dependent on the physical characteristics of the device; and it is desirable for the semiconductor device 100 to satisfy R1<R2<(R3−R4−Wmax). The distance R3 from the upper surface 51a to the lower surface 52a is the thickness of the collector layer 12, the first buffer layer 13a, the second buffer layer 13b, the drift layer 11, the base layer 15, and the emitter layer 16. The distance R4 from the lower portion 41a to the lower surface 52a is the trench depth of the semiconductor device 100. The occurrence of oscillations can be suppressed by the impurity concentration of the first peak P1 being greater than the impurity concentration of the second peak P2, i.e., R1<R2 being satisfied. By satisfying R2<(R3−R4−Wmax), a peak voltage increase can be suppressed.

In the semiconductor device 100, Wmax is represented by the following formula (1), in which q is the absolute value of the charge of an electron, ε is the permittivity of the drift layer 11, Nd is the third impurity concentration per unit volume of the drift layer 11, Vs is the saturation velocity of holes, Vce is the voltage between the first electrode 51 and the third electrode 53, Ic is the rated current, γₕ is the ratio of the hole current at turn-off, and AA is the area of the second electrode 52 in a plane including the second direction D2 which crosses the first direction D1 and a third direction D3 which crosses the second direction D2. The area AA is the area of the region in which current mainly flows during operation of the semiconductor device 100. The area AA is the area of the second electrode 52 in the XY-plane, and is the area of the active area.

$$\begin{matrix}[ Formula 1 ] & \\ {W}_{max} = \sqrt{\frac{2 ε {V}_{ce}}{( {N}_{d} + \frac{{I}_{c} {γ}_{h}}{{qV}_{s} \times AA} )}} & ( 1 )\end{matrix}$$

The permittivity ε is, for example, the permittivity of the silicon included in the drift layer 11. The voltage Vce is, for example, the rated voltage or about 80% of the rated voltage. The ratio γₕ of the hole current at turn-off, as estimated from actual measurement data of the turn-off operation, is, for example, not less than 0.7 and not more than 0.9. For example, the value of 0.8 is substituted into formula (1) as the ratio γₕ of the hole current at turn-off. It is desirable for the value of Wmax estimated by formula (1) to satisfy R2<(R3−R4−Wmax).

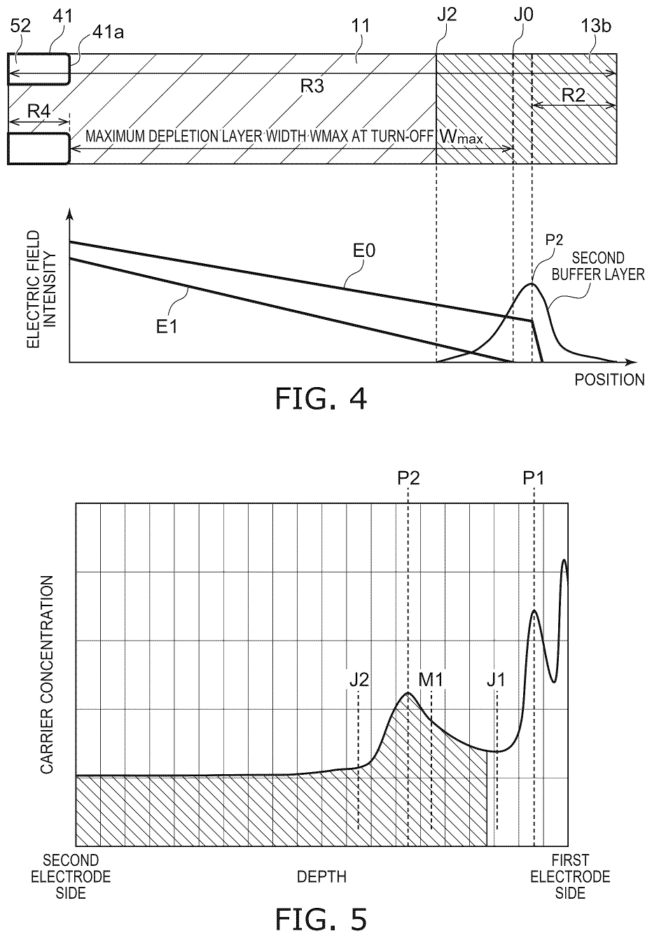

FIG. 4 is a schematic view describing the width of the maximum depletion layer of the semiconductor device according to the embodiment.

For the width Wmax of the maximum depletion layer of the drift layer 11 at turn-off in the semiconductor device 100, a lower end J0 of the maximum depletion layer is further toward the second electrode 52 side than the second peak P2 of the second buffer layer 13b. The combined length of the width Wmax of the maximum depletion layer and the distance R2 is less than the distance R4 subtracted from the distance R3. As a result, as illustrated by a characteristic E1, a peak voltage increase is suppressed. If the lower end J0 of the maximum depletion layer is further toward the first electrode 51 side, i.e., the side opposite to the second electrode 52, than the apex of the second peak P2 of the second buffer layer 13b, the peak voltage increases as illustrated by a characteristic E0. The junction position is described below.

It is therefore desirable for the semiconductor device 100 to satisfy R1<R2<(R3−R4−Wmax).

It is desirable to satisfy Qdp>4.27×10⁻³×Nd+2.41×10¹¹ cm⁻², in which Qdp (cm⁻²) is the total dose of the dose of the drift layer 11 and the dose of the second buffer layer 13b, and Nd (cm⁻³) is the impurity concentration of the drift layer 11. Here, the units of Nd are cm⁻³. The total dose Qdp is described below.

FIG. 5 describes the total dose Qdp of the dose of the drift layer 11 and the dose of the second buffer layer 13b.

The vertical axis of FIG. 5 is the carrier concentration per unit volume with respect to the depth from the first electrode 51 to the second electrode 52. FIG. 5 also shows the first peak P1 of the first buffer layer 13a, the second peak P2 of the second buffer layer 13b, a junction position J1 (a first junction position) between the first and second buffer layers 13a and 13b, a central position M1 of the second buffer layer 13b in the first direction D1 (the midpoint in the thickness direction of the second buffer layer 13b), and a junction position J2 (a second junction position) between the second buffer layer 13b and the drift layer 11. The junction position J1 is the depth position at which the carrier concentration between the first peak P1 and the second peak P2 has a minimum. The central position M1 is the midpoint in the depth direction between the junction position J1 and the junction position J2. The junction position J2 is, for example, the depth position at which the impurity concentration reaches a value of the impurity concentration of the drift layer 11 added to 5% of an absolute value of the difference between the impurity concentration of the drift layer 11 and the impurity concentration of the second peak P2 of the second buffer layer 13b.

The total dose Qdp of the dose of the drift layer 11 and the dose of the second buffer layer 13b is the impurity amount per unit area (XY-plane) of the carrier concentration per unit volume integrated in the depth direction from the junction position J1, i.e., the point at which the carrier concentration has a minimum between the first peak P1 and the second peak P2, to the lower portion 41a.

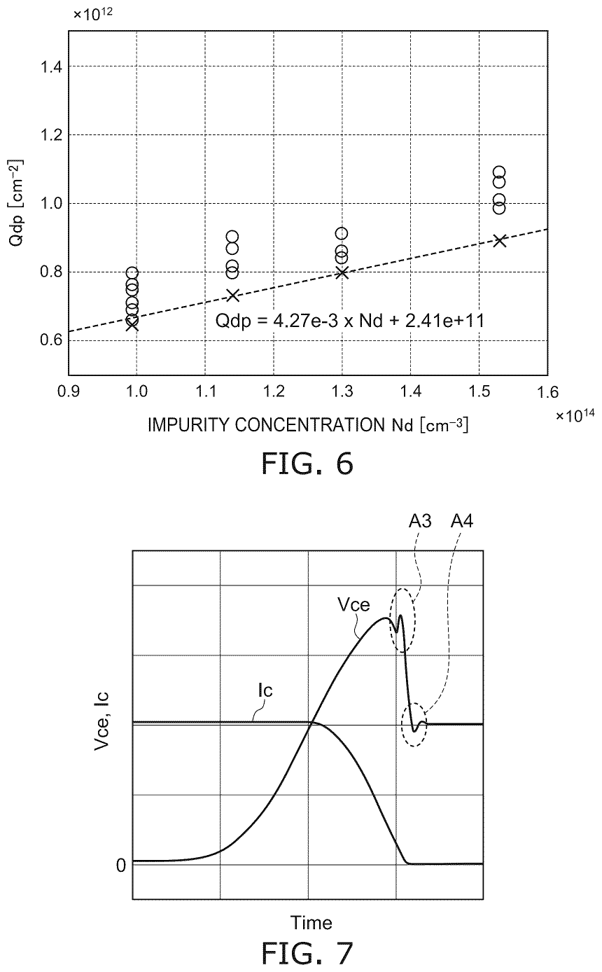

FIG. 6 describes conditions of the total dose of the semiconductor device according to the embodiment based on simulation results. FIG. 6 shows results of a simulation in which the impurity concentration Nd (the third impurity concentration) of the drift layer and the total dose Qdp are changed.

FIG. 7 illustrates characteristics when the distance from the upper surface to the apex of the second peak is less than a prescribed distance. FIG. 7 shows an example of the temporal change of the voltage Vce and the rated current Ic.

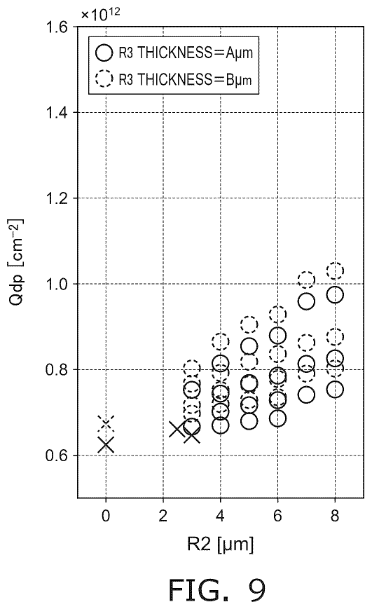

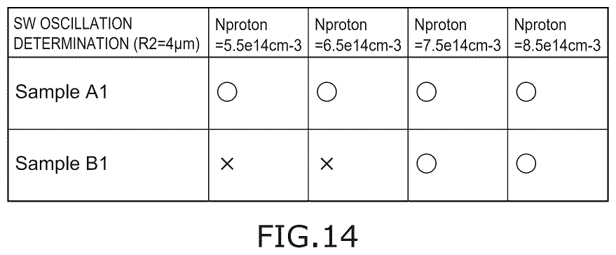

The circles shown in FIG. 6 and in FIGS. 9 and 14 below are results of simulations in which neither the waveform indicating an oscillation at the peak voltage vicinity shown in area A3 of FIG. 7 nor the waveform indicating an oscillation in area A4 are present, or results in which one of the waveform indicating the peak voltage increase shown in area A3 or the waveform indicating the oscillation of area A4 is not present. The crosses are results of the simulation in which both the waveform indicating the oscillation at the peak voltage vicinity shown in area A3 and the waveform indicating the oscillation of area A4 are present.

As shown in FIG. 6, if Qdp falls below 4.27×10⁻³×Nd+2.41×10¹¹ cm⁻², multiple peaks occur in the voltage waveform as shown in area A3 surrounded with a broken line in FIG. 7. Furthermore, an oscillation waveform occurs after turn-off as shown in area A4. As a result, it is desirable for the semiconductor device 100 to satisfy Qdp>4.27×10⁻³×Nd+2.41×10¹¹. The occurrence of oscillations can be suppressed thereby.

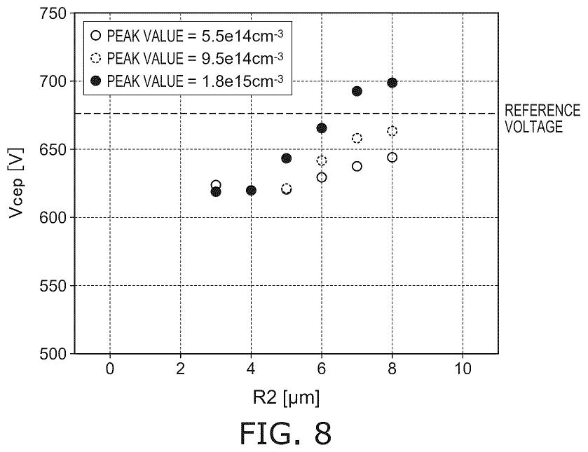

FIG. 8 shows the relationship of the peak voltage between the first electrode and the third electrode with respect to the distance from the upper surface to the apex of the second peak. FIG. 8 shows samples in which the concentration peak value Nproton is 5.5×10¹⁴/cm³, 9.5×10¹⁴/cm³, and 1.8×10¹⁵/cm³, in which Nproton is the concentration peak value of the second impurity concentration.

As shown in FIG. 8, the rise of the peak voltage is steep as the distance R2 from the upper surface 51a to the apex of the second peak P2 increases in the sample of 1.8×10¹⁵/cm³. There is a risk that the reference voltage may be exceeded if the distance R2 becomes large. For example, the reference voltage is a constant multiple (80 to 90%) of the rated voltage, and in the example of FIG. 8, is 675 V (750 V×90%). As a result, it is desirable for the semiconductor device 100 to satisfy Nproton≤1.8×10¹⁵/cm³ or Nproton<1.8×10¹⁵/cm³. A peak voltage increase can be suppressed thereby. Because the peak voltage increase can be suppressed as the concentration peak value Nproton decreases, it is desirable to satisfy Nproton≤9.5×10¹⁴/cm³ and Nproton≤5.5×10¹⁴/cm³.

According to the semiconductor device 100, by setting the positions of the apexes of the first and second peaks P1 and P2 and the impurity concentrations to have the configuration described above, a peak voltage increase can be suppressed, and oscillations after turn-off can be suppressed.

As shown in FIG. 3, the second impurity concentration gradually decreases toward the first electrode 51. The second impurity concentration also gradually decreases from the second peak P2 toward the drift layer 11. The first peak P1 and the second peak P2 have steep shapes rather than broad shapes. The second peak P2 has a steep shape at the second electrode 52 side. In FIG. 5, the central position M1 is positioned further toward the first electrode 51 side than the position of the second peak P2. In other words, the distance in the depth direction between the junction position J2 and the position of the second peak P2 is less than the distance in the depth direction between the junction position J1 and the position of the second peak P2. The widths at half maximum of the first and second peaks P1 and P2 may be 3 μm or less.

The number of the second peaks P2 of the second impurity concentration may be 1. On the other hand, the second peak P2 may include multiple second peaks P2. In such a case, the distance R2 from the upper surface 51a to the apex of the second peak P2 is the distance to the apex of the peak among the multiple second peaks P2 most proximate to the drift layer 11.

FIG. 9 is results showing the presence or absence of oscillation waveforms of areas A3 and A4 of FIG. 7, in which the total dose Qdp and the distance R2 are changed.

In FIG. 9, a simulation is performed for two types of distances R3 (the thickness of the collector layer 12, the first buffer layer 13a, the second buffer layer 13b, the drift layer 11, the base layer 15, and the emitter layer 16).

As shown in FIG. 9, if the distance R2 from the upper surface 51a to the apex of the second peak P2 is not more than 3 μm, there is a risk that an oscillation after turn-off may occur if the total dose Qdp is too small. On the other hand, when the distance R2 is not less than 4 μm, favorable results are obtained for various values of the total dose Qdp, and a favorable waveform is obtained for oscillations after turn-off. As a result, it is favorable for the semiconductor device 100 to satisfy 4 μm≤R2 and 4 μm<R2.

Increasing the lower limit of R2 tends to suppress oscillations better. As a result, it is favorable for the semiconductor device 100 to satisfy 5 μm≤R2, 6 μm≤R2, 7 μm≤R2, and 8 μm≤R2.

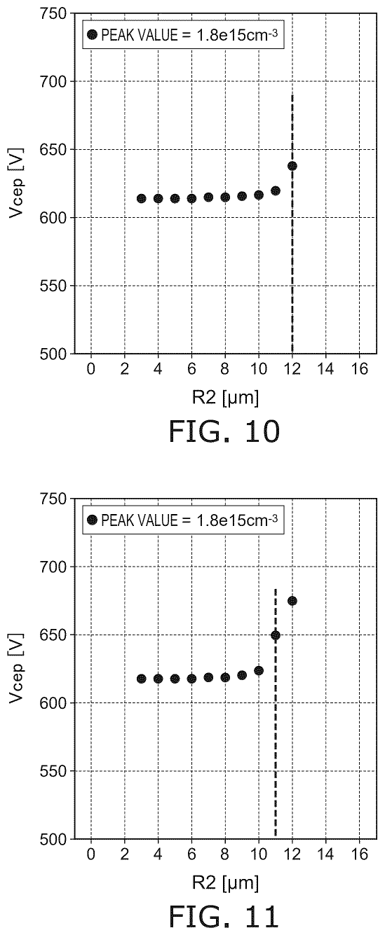

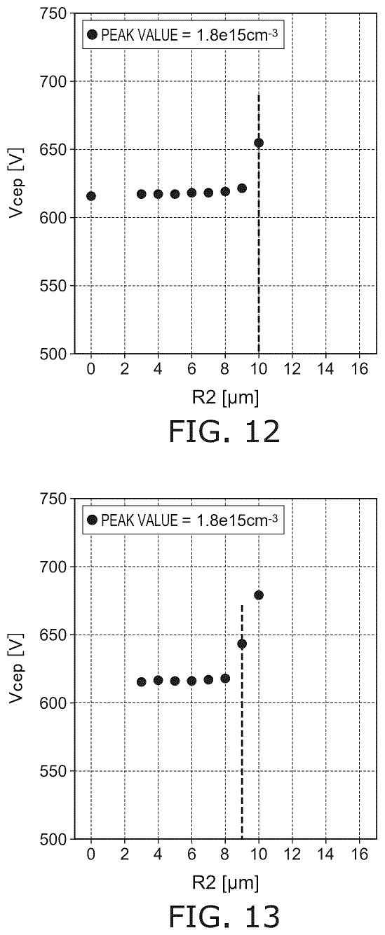

FIGS. 10 to 13 show the relationship of the peak voltage between the first electrode and the third electrode with respect to the distance from the upper surface to the apex of the second peak. The peak voltage is the maximum value of the Vce waveform of FIG. 7, and is referred to as Vcep. FIGS. 10 to 13 show samples in which the concentration peak value Nproton of the second impurity concentration is 1.8×10¹⁵/cm³. FIG. 10 shows a sample in which the resistivity is 30 Ωcm. FIG. 11 shows a sample in which the resistivity is 35 Ωcm. FIG. 12 shows a sample in which the resistivity is 40 Ωcm. FIG. 13 shows a sample in which the resistivity is 46 Ωcm.

In the sample shown in FIG. 10 in which the resistivity is 30 Ωcm, there is a tendency for the peak voltage Vcep to increase above 12 μm. As a result, it is favorable for the distance R2 from the upper surface 51a to the apex of the second peak P2 to satisfy R2<12 μm. In the sample shown in FIG. 11 in which the resistivity is 35 Ωcm, there is a tendency for the peak voltage Vcep to increase for 11 μm or more. As a result, it is favorable for the semiconductor device 100 to satisfy R2<11 μm. In the sample shown in FIG. 12 in which the resistivity is 40 Ωcm, there is a tendency for the peak voltage Vcep to increase for 10 μm or more. As a result, it is favorable for the semiconductor device 100 to satisfy R2<10 μm. In the sample shown in FIG. 13 in which the resistivity is 46 Ωcm, there is a tendency for the peak voltage Vcep to increase for 9 μm or more. As a result, it is favorable for the semiconductor device 100 to satisfy R2<9 μm. FIGS. 10, 11, 12, and 13 show samples in which the resistivity increases in the order of FIGS. 10, 11, 12, and 13, but the distance R2 at which the peak voltage Vcep jumps decreases as the resistivity increases, and so a shorter distance R2 is better.

FIG. 14 shows simulation results showing the presence or absence of oscillations of the voltage waveforms of the samples with respect to concentration peak values of the second impurity concentration.

In Sample A1 of FIG. 14, the resistivity is 46 Ωcm; and the distance R3 from the upper surface 51a to the lower surface 52a is 70 μm. In Sample B1, the resistivity is 35 Ωcm; and the distance R3 from the upper surface 51a to the lower surface 52a is 65 μm. The distance R2 from the upper surface 51a to the apex of the second peak P2 is 4 μm.

As shown in FIG. 14, the oscillation waveform characteristics are better when the concentration peak value Nproton of the second impurity concentration is 7.5×10¹⁴/cm³ than when the concentration peak value Nproton of the second impurity concentration is 6.5×10¹⁴/cm³. There is a tendency for the characteristics to improve as the concentration peak value Nproton of the second impurity concentration increases. As a result, it is favorable for Nproton to satisfy 6.5×10¹⁴/cm³<Nproton. It is also favorable to satisfy 7.5×10¹⁴/cm³≤Nproton.

The first impurity may include phosphorus. The concentration peak value of the first impurity concentration may be not less than 2×10¹⁶/cm³ and not more than 3×10¹⁶/cm³.

The concentration peak value of the second impurity concentration may be not less than 0.02 times and not more than 0.06 times the concentration peak value of the first impurity concentration (e.g., the concentration peak value of the first impurity concentration may be 3×10¹⁶/cm³). The concentration peak value of the second impurity concentration may be not less than 0.03 times and not more than 0.09 times the concentration peak value of the first impurity concentration (e.g., the concentration peak value of the first impurity concentration may be 2×10¹⁶/cm³).

The second buffer layer 13b is formed by proton irradiation. The second impurity may include protons.

The first electrode 51, the second electrode 52, and the third electrode 53 include a metal material such as aluminum, copper, etc. The drift layer 11, the collector layer 12, the first buffer layer 13a, the second buffer layer 13b, the base layer 15, the emitter layer 16, and the contact layer 17 may include silicon, silicon carbide, gallium nitride, or gallium arsenide as a semiconductor material. Arsenic, phosphorus, or antimony can be used as the impurity of the first conductivity type when silicon is used as the semiconductor material. The third impurity includes, for example, arsenic, phosphorus, or antimony. Boron can be used as the impurity of the second conductivity type. The third electrode 53 may include conductive polysilicon to which an impurity is added, or another conductive material. The insulating layer 40 and the gate insulating film 41 include an insulating material such as silicon oxide, silicon nitride, silicon oxynitride, etc.

In this specification, “perpendicular” and “parallel” include not only strictly perpendicular and strictly parallel but also, for example, the fluctuation due to manufacturing processes, etc.; and it is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components such as first buffer layers, second buffer layers, etc., included in the semiconductor device from known art. Such practice is within the scope of the invention to the extent that similar effects thereto are obtained.

Furthermore, any two or more components of the specific examples may be combined within the extent of technical feasibility, and are within the scope of the invention to the extent that the purport of the invention is included.

Moreover, all semiconductor devices practicable by an appropriate design modification by one skilled in the art based on the semiconductor devices described above as exemplary embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first electrode including an upper surface;
a collector layer located on the first electrode, the collector layer being of a second conductivity type;
a first buffer layer located on the collector layer, the first buffer layer being of a first conductivity type and including a first impurity;
a second buffer layer located on the first buffer layer, the second buffer layer being of the first conductivity type and including a second impurity;
a drift layer located on the second buffer layer, the drift layer being of the first conductivity type and including a third impurity;
a base layer located on the drift layer, the base layer being of the second conductivity type;
an emitter layer located on the base layer, the emitter layer being of the first conductivity type;
a second electrode located on the emitter layer, the second electrode including a lower surface;
a third electrode located between a portion of the second electrode and a portion of the drift layer; and
a gate insulating film located at least between the third electrode and the base layer, the gate insulating film including a lower portion,
the first buffer layer including a first peak of a concentration of the first impurity in a first direction, the first direction being from the first electrode toward the second electrode,
the second buffer layer including a second peak of a concentration of the second impurity in the first direction,
R1<R2<(R3−R4−Wmax) being satisfied, R1 being a distance from the upper surface to an apex of the first peak, R2 being a distance from the upper surface to an apex of the second peak, R3 being a distance from the upper surface to the lower surface, R4 being a distance from the lower portion to the lower surface, Wmax being a width of a maximum depletion layer of the drift layer at turn-off,
Wmax being expressed by formula (1), q being an absolute value of a charge of an electron, ε being a permittivity of the drift layer, Nd being a concentration of the third impurity of the drift layer, Vs being a saturation velocity of holes, Vce being a voltage between the first electrode and the third electrode, Ic being a rated current, γₕ being a ratio of a hole current at turn-off, AA being an area of the second electrode in a plane including a second direction and a third direction, the second direction crossing the first direction, the third direction crossing the first and second directions,
$${W}_{max} = \sqrt{\frac{2 ε {V}_{ce}}{( {N}_{d} + \frac{{I}_{c} {γ}_{h}}{{qV}_{s} \times AA} )}} \qquad ( 1 )$$
Qdp>4.27×10⁻³×Nd+2.41×10¹¹ cm⁻² being satisfied, Qdp (cm⁻²) being a total dose of a dose of the drift layer and a dose of the second buffer layer, Nd having units of cm⁻³,
Nproton<1.8×10¹⁵/cm³ being satisfied, Nproton being a concentration of the second peak.

2. The semiconductor device according to claim 1, wherein
a width at half maximum of the second peak is not more than 3 μm.

3. The semiconductor device according to claim 1, wherein
the concentration of the second impurity gradually decreases from the second peak toward the drift layer.

4. The semiconductor device according to claim 3, wherein
a number of the second peaks of the concentration of the second impurity is 1.

5. The semiconductor device according to claim 1, wherein
the second buffer layer includes a plurality of peaks including the second peak, and
the distance R2 is a distance from the upper surface to an apex of a peak among the plurality of peaks most proximate to the drift layer.

6. The semiconductor device according to claim 1, wherein
the distance R2 satisfies 4 μm<R2<12 μm, and
the concentration Nproton satisfies 7.5×10¹⁴/cm³<Nproton.

7. The semiconductor device according to claim 1, wherein
the first impurity includes phosphorus, and
a concentration of the first peak is not less than 2×10¹⁶/cm³ and not more than 3×10¹⁶/cm³.

8. The semiconductor device according to claim 7, wherein
the concentration of the second peak is not less than 0.02 times and not more than 0.06 times the concentration of the first peak.

9. A semiconductor device, comprising:
a first electrode including an upper surface;
a collector layer located on the first electrode, the collector layer being of a second conductivity type;
a first buffer layer located on the collector layer, the first buffer layer being of a first conductivity type and including a first impurity;
a second buffer layer located on the first buffer layer, the second buffer layer being of the first conductivity type and including a second impurity;
a drift layer located on the second buffer layer, the drift layer being of the first conductivity type and including a third impurity;
a base layer located on the drift layer, the base layer being of the second conductivity type;
an emitter layer located on the base layer, the emitter layer being of the first conductivity type;
a second electrode located on the emitter layer, the second electrode including a lower surface;
a third electrode located between a portion of the second electrode and a portion of the drift layer; and
a gate insulating film located at least between the third electrode and the base layer, the gate insulating film including a lower portion,
the first buffer layer including a first peak of a concentration of the first impurity in a first direction, the first direction being from the first electrode toward the second electrode,
the second buffer layer including a second peak of a concentration of the second impurity in the first direction,
a central position being a midpoint between a first junction position between the first buffer layer and the second buffer layer and a second junction position between the second buffer layer and the drift layer,
the central position being positioned further toward the first electrode side than a position of the second peak,
a distance R2 from the upper surface to an apex of the second peak satisfying 4 μm<R2<12 μm.

10. The semiconductor device according to claim 9, wherein
a width at half maximum of the second peak is not more than 3 μm.

11. The semiconductor device according to claim 9, wherein
the concentration of the second impurity gradually decreases from the second peak toward the drift layer.

12. The semiconductor device according to claim 11, wherein
a number of the second peaks of the concentration of the second impurity is 1.

13. The semiconductor device according to claim 9, wherein
the second buffer layer includes a plurality of peaks including the second peak, and
the distance R2 is a distance from the upper surface to an apex of a peak among the plurality of peaks most proximate to the drift layer.

14. The semiconductor device according to claim 9, wherein
the first impurity includes phosphorus, and
a concentration of the first peak is not less than 2×10¹⁶/cm³ and not more than 3×10¹⁶/cm³.

15. The semiconductor device according to claim 14, wherein
a concentration of the second peak is not less than 0.02 times and not more than 0.06 times the concentration of the first peak.

16. The semiconductor device according to claim 9, wherein
7.5×10¹⁴ cm⁻³≤Nproton<1.8×10¹⁵ cm⁻³ is satisfied, and
Nproton is a concentration of the second peak.
